(19) United States
(12) Patent Application Publication
(10) Pub. No.: US 2011/0089537 A1
(43) Pub. Date: Apr. 21, 2011

(54) GROWING PROCESS FOR GROUP III NITRIDE ELEMENTS

(75) Inventors: Bernard Gil, Montpellier (FR); Olivier Briot, Jacou (FR); Matthieu Moret, Montpellier (FR); Sandra Ruffenach, Montarnaud (FR)

(73) Assignees: CENTRE NATIONAL DE LA RECHERCHE SCIENTIFIQUE (CNRS), Paris (FR); UNIVERSITE MONTPELLIER 2 SCIENCES ET TECHNIQUES, Montpellier (FR)

(21) Appl. No.: 12/997,796

(22) PCT Filed: Jun. 12, 2009
(86) PCT No.: PCT/EP2009/057273

§ 371 Date: Dec. 13, 2010

(30) Foreign Application Priority Data
Jun. 13, 2008 (FR) 0853943

(51) Int. Cl. H01L 29/20; C23C 14/34; C30B 23/06; H01L 21/20

(52) U.S. Cl. 257/615; 204/192.1; 117/108; 438/478; 257/E21.09; 257/E29.089

(57) ABSTRACT

The disclosure relates to a method for growing an element III nitride, wherein the growth is carried out on a substrate made of a material capable of maintaining the same crystalline structure from the element III nitride growth temperature to room temperature, the substrate being an M-V—O₄ alloy, where M denotes a transition metal or a Group III element, and where V denotes N, P, S, or Sb, or an (Si-IV)O₂ alloy, where IV denotes a Group IV element other than silicon. The disclosure also relates to the structures and components obtained after the implementation of the method.

### CROSS-REFERENCE TO RELATED APPLICATIONS

This application is a National Phase Entry of International Application No. PCT/EP2009/057273, filed on Jun. 12, 2009, which claims priority to French Application 0853943, filed on Jun. 13, 2008, both of which are incorporated by reference herein.

### BACKGROUND AND SUMMARY

The field of the invention is that of structures designated for applications in optics, optoelectronics or microelectronics. The invention relates more particularly to the production of such structures by growing on a substrate films or nano-objects based on nitride of element of group III.

The nitrides of element of group III (InN, GaN, AlN), their alloys and their heterostructures present highly interesting properties for applications in electronics and in optoelectronics. In particular, the ensemble (Al,Ga,In)—N describes the entire electromagnetic spectrum of interest to communications and information-processing technologies, from near infrared to type-C ultraviolet. The result is that their optoelectronic applications are wider than those of other families of semi-conductor material.

The prohibited indium nitride InN band corresponds to a wavelength of around 1.8 μm, that of aluminium nitride AlN to 200 nm and that of gallium nitride GaN to 350nm. As it is known how to make alloys whereof the composition varies continuously between the three binaries In, Al and Ga, as it is also known how to assemble these binaries into heterostructures with quantic wells and boxes, it is possible to cover telecommunications bands at 1.3 μm and 1.5 μm from these materials, or to make visible light-emitting devices (electroluminescent diodes, lasers) or even to make photodetectors visible-blind to the sun.

Otherwise, the exceptional resistance of nitrides of element III to strong tensions makes them candidates a priori incontrovertible for high-frequency applications. Applications as sensors and other types of mechanical microsystems are also feasible, given the piezoelectric properties of nitrides. The nitrides of element III are also chemically inert, and thus do not exhibit the same dangers as arsenic, phosphorous or antimony in terms of pollution. This family of materials respects the environmental constraints prescribed during the signing of the Kyoto protocol.

The development of technologies based on nitrides of element III, and especially indium nitride, has until now been limited by the difficulties associated with growing these materials. Among the nitrides of element III, indium nitride is the most difficult to synthesise with a crystalline quality compatible with the envisaged applications. The incorporation of indium into the crystalline matrix of the nitride cannot be done effectively without generating strong strains and numerous dislocations of networks with deleterious consequences for any electronic component.

It is thus still impossible these days to produce a film of InN of sufficient quality, especially in terms of crystallinity, for the envisaged applications. The lack of substrate adapted to the growing of InN constitutes a technological glitch which limits the use of nitrides outside the confines of blue and ultraviolet. It would be preferable to be able to alloy gallium or aluminium with indium in solid phases exempt from excessive densities of dislocations to be able to make optoelectronic components operating at 1.3 and 1.5 μm and thus likely to address regions of transparency of fibre optics in place of optoelectronic components based on phosphorous, arsenic and antimony.

An aim of the invention is to enable synthesis of films or nano-objects based on nitride of element of group III exhibiting a crystalline quality greater than what exists in the prior art, so as to be able to fully exploit the properties of these materials industrially. For this purpose, according to a first aspect, the invention proposes a process for growing element III nitride, in which the growing is carried out on a substrate made of material suitable for retaining the same crystalline structure from the growing temperature of the element III nitride to ambient temperature, the substrate being an alloy of M-V—O₄ type, where M designates a transition metal or an element of group III, and where V designates N, P, As or Sb, or an alloy of (Si-IV)O₂ type, where IV designates an element of group IV other than silicon.

Some preferred, though non-limiting, aspects of this process are the following:
indium nitride InN is deposited on a AlPO₄ substrate;
gallium nitride GaN is deposited on a GaPO₄ substrate;
an alloy constituted by GaN and GaInN is deposited on a GaPO₄ substrate;
growing the element III nitride on the substrate is carried out by epitaxy; and
the growing of the element III nitride on the substrate is carried out by pulverisation.

According to another aspect, the invention relates to a structure for application in electronics, optics or optoelectronics, comprising an element III nitride deposited on a substrate made of material suitable for retaining the same crystalline structure from the growing temperature of the element III nitride to ambient temperature, the substrate being an alloy of type M-V—O₄, where M designates a transition metal or an element of group III, and where V designates N, P, As or Sb, or an alloy of the type (Si-IV)O₂, where IV designates an element of group IV other than silicon. According to yet another aspect, the invention also relates to components comprising a structure such as described previously.

### BRIEF DESCRIPTION OF THE DRAWINGS

Other aspects, aims and advantages of the present invention will emerge more clearly from the following detailed description of preferred embodiments thereof, given by way of non-limiting example, and in reference to the attached diagrams, in which:

FIG. 1 is an atomic-force microscopy image exhibiting the morphology of a AlPO₄ substrate;

FIG. 2 illustrates a diffraction spectrum of X-rays indicating the crystallinity of the AlPO₄ substrate;

FIG. 3 is an atomic-force microscopy image exhibiting the indium nitride morphology deposited on an AlPO₄ substrate according to the invention;

FIG. 4 illustrates a diffraction spectrum of X-rays indicating the indium nitride crystallinity deposited on an AlPO₄ substrate according to the invention; and

FIG. 5 illustrates a fluorescence spectrum indicating the indium nitride light emission deposited on an AlPO₄ substrate according to the invention.

### DETAILED DESCRIPTION

According to a first aspect, the invention relates to a process for growing element III nitride on a substrate, in which the growing is carried out on a substrate made of material suitable for retaining the same crystalline structure from the growing temperature of the element III nitride to ambient temperature. The nitrides of elements of group III of the Mendeleiev table are in particular aluminium nitride, gallium nitride and indium nitride as well as mixed nitrides. Indium nitride is a particular focus, but the invention is in no way limited to this particular nitride, but on the contrary can extend to other nitrides of element III as well as to their heterostructures.

According to the invention, “film” means a continuous layer, preferably a thin layer, of thickness generally between 1 atomic monolayer and 10 microns. According to the invention, “nano-object” means an individual structure exhibiting at least one nanometric dimension, between 1 and 50nm.

The element III nitride whereof the growing by the process according to the first aspect of the invention can especially be a film or a nano-object such as a quantic box. The invention equally relates to films of nitrides of elements III and their heterostructures, wells and quantic boxes as well as objects generally used in photonics: microcavities, technologically textured or selectively induced during growing photonic membranes, photonic crystals made by crossed 3-D growing (“wood” pile stacking).

The substrate used within the scope of the invention for growing element III nitride is preferably a compound of the family of quartz and berlinite. These materials, composed of the ordered phase type M-V-O₄ (where M designates a transition metal or an element of group III, and where V designates N, P, As or Sb) or alloys of type (Si-IV)O₂ (where IV designates an element of group IV other than silicon), have the advantage of a transition temperature of alpha-beta structure phase or alpha-cristobalite higher than the synthesis temperature of the element III nitride. The growing of the element III nitride can be carried out on a substrate whereof the crystalline nature is retained after growing said nitride when the system is returned to ambient temperature (component-operating temperature).

It is evident that quartz SiO₂ has a relatively low transition temperature of alpha-beta structural phase (573° C). In function of the type of element III nitride considered, quartz SiO₂ is thus not likely to retain the same crystalline structure from the nitride growing temperature to ambient temperature. This conservation for all nitrides of the crystalline structure is possible however for the substrates presented hereinabove (M-V—O₄ and (Si-IV)O₂) for which the transition temperature of alpha-beta structural phase is higher than that of quartz, or even replaced by the transition of alpha-cristobalite structural phase at even higher temperature.

In this respect, the table below points out the transition temperatures of structural phase for different examples of substrates which can be used within the scope of the invention. These substrates are obtained by hydrothermal growing, a technique described in the work “Handbook of Hydrothermal Technology” (2001)*, by K. Byrappa and M. Yoshimura (ISBN: * 081551445X/9780815514459, editor: William Andrew Inc.).

| | Quartz α | Quartz α | |
|---|---|---|---|
| | to | to Cristo- | Fusion or |
| Material | Quartz β | balite α | decomposition |
| AlAsO₄ | 571° C. | | 950° C. |
| SiO₂ | 573° C. | | 1710° C. |
| AlPO₄ | 586° C. | | 1600° C. |
| FePO₄ | 707° C. | | 1240° C. |
| MnPO₄ | none | 813° C. | |
| GaPO₄ | none | 933° C. | 1670° C. |
| GeO₂ | none | | 1120° C. |
| GaAsO₄ | none | none | <1000° C. |

The growing temperature of the element III nitride on a substrate varies according to the nitride. Indium nitride InN is always deposited at a temperature less than its decomposition temperature of 600° C. Gallium nitride GaN is as such generally deposited at a temperature of around 800° C.

It is understood within the scope of the invention that the choice of substrate must integrate this parameter. So, by way of example, a substrate of GaPO₄ appears as being appropriate for depositing a film of GaN and GaInN-GaN heterostructures from which are made electroluminescent blue diodes, compact blue lasers and transistors. By way of example also, an AlPO₄ substrate is appropriate for growing indium nitride.

According to a preferred embodiment of the invention, growing of the element III nitride is carried out by epitaxy. By way of examples, the growing can be carried out by epitaxy under molecular jet (“MBE” from the English acronym “Molecular Beam Epitaxy”), by epitaxy via deposit of organo-metallics in steam phase (“MOVPE” from the English acronym “MetalOrganic Vapor Phase Epitaxy”), by HWE epitaxy (from the English acronym “Hot Wall Epitaxy”), by MEE epitaxy (from the English acronym “Migration Enhanced Epitaxy”). According to another embodiment, the growing of the element III nitride is carried out by pulverisation (“sputtering”). In pulverisation, the material sources are evaporated, either thermally, or by electronic bombardment, and condense on the surface of the substrate, at low temperature. Due to the moderate temperature of the substrate, the crystalline quality of the material deposited is less, and for most of the time it is polycrystalline.

Prior to carrying out growing of the element III nitride, the surface of the substrate can undergo a surface preparation step for improving its physical properties for growing. One or more of the following techniques can be employed: thermal processing, polishing, chemical etching, or other techniques known to the person skilled in the art. The process described produces films and nano-objects of nitrides of elements III exhibiting good crystalline quality, with especially reduced density of dislocations. The resulting structures are compatible with applications envisaged in electronics, optics or optoelectronics.

According to a second aspect, the invention relates to a structure for application in electronics, optics or optoelectronics, comprising one or more films or one or more nano-objects of element III nitride, carried by a substrate made of material suitable for retaining the same crystalline structure from the growing temperature of the element III nitride to ambient temperature, in particular a substrate of type M-V-O₄ or (Si-IV)O₂ such as described previously. According to a third aspect, the invention relates to a component for electronics, optics or optoelectronics, comprising a structure according to the second aspect of the invention.

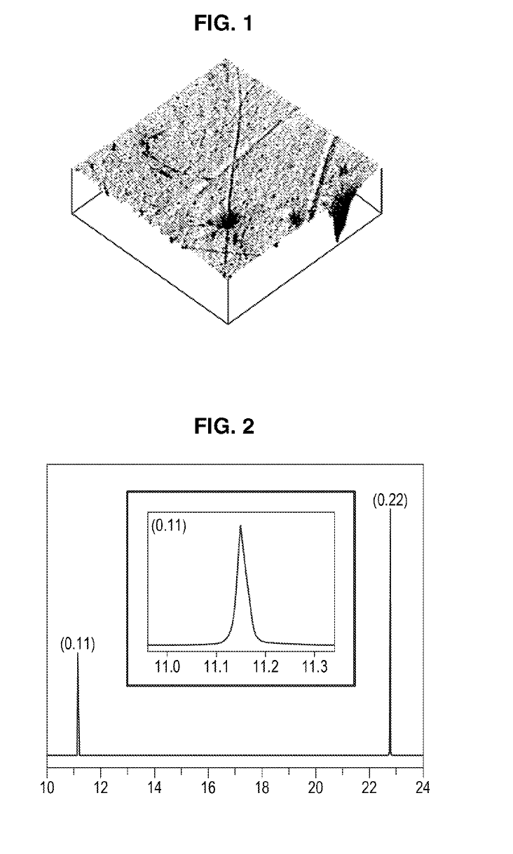

In reference to FIGS. 1 to 5, an embodiment of a structure according to the invention by growing a film of indium nitride will be described hereinbelow. It is understood that indium nitride is the most difficult material to synthesise from materials of the III-N family.

Indium nitride is deposited by epitaxial growing, MOCVD, on an AIPO4 substrate. The growing parameters used are typically a growing temperature of 500° C., a pressure in the reactor of 200 mBar and a V/III ratio of the order of 20,000. It is evident that the value of the molar ratio V/III correlates strongly with the type of growing reactor used. This molar ratio especially affects the stoechiometry of the material worked on; an excessively low molar ratio V/III will translate into films containing metallic indium. It is also evident that the pressure in the reactor can generally be selected between 20 and 1000 mBar. Finally, the growing temperature is limited to the interval 250° C.-650° C., the indium nitride dissociation temperature being effectively around 700° C.

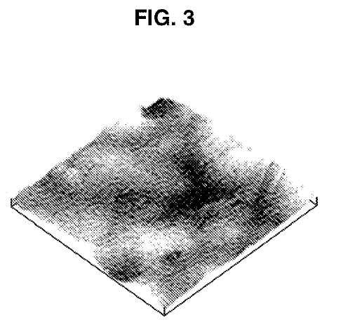

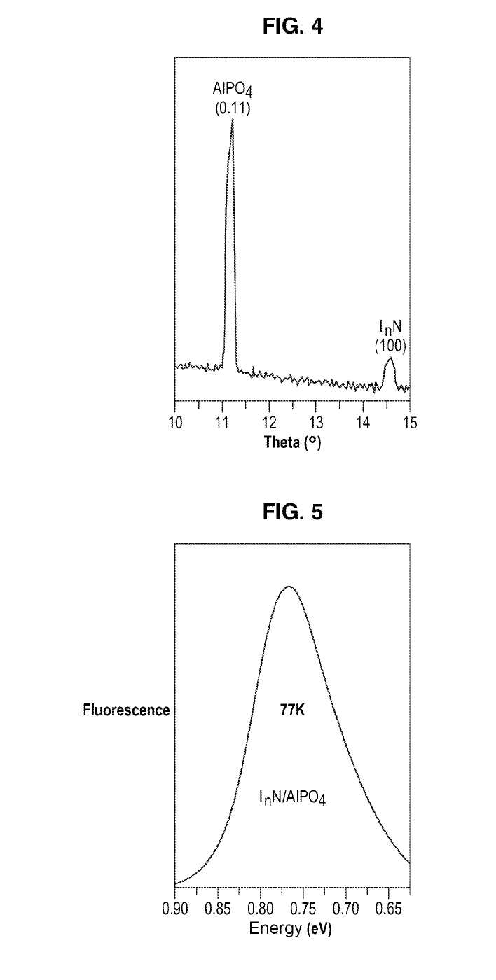

FIG. 1 illustrates the morphology of the AlPO4 substrate (such as observed via atomic-force microscope). FIG. 2 illustrates the crystallinity of the AlPO₄ substrate (observed by X-ray spectrography; the X axis representing the angular deviation of the X-rays incident beam and the Y axis showing the accumulated electromagnetic intensity). FIG. 3 illustrates the indium nitride morphology deposited on the AlPO₄ substrate (observed via atomic force microscope), in FIG. 4 the crystallinity of this indium nitride (observed by X-ray spectrography) and in FIG. 5 the fluorescence spectrum of this indium nitride (obtained at 77 K). These FIGS. 3, 4 and 5 indicate respectively an excellent morphology, a remarkable crystallographic quality (demonstrated by the finesse of the peak linked to the indium nitride in FIG. 4, 11 arcmin), and a fluorescence, comparable to the state of the art.

1. A process for growing element III nitride, the process comprising carrying out the growing on a substrate made of material suitable for retaining the same crystalline structure from the growing temperature of the element III nitride to ambient temperature, the substrate being an alloy of type M-V—O₄, where M designates a transition metal or an element of group III, where V designates N, P, As or Sb, or an alloy of the type (Si-IV)O₂, and where IV designates an element of group IV other than silicon.

2. The process as claimed in claim 1, wherein the element III nitride is indium nitride InN, and the substrate is an AlPO₄ substrate.

3. The process as claimed in claim 1, wherein the element III nitride is gallium nitride GaN, and the substrate is a GaPO₄ substrate.

4. The process as claimed in claim 1, wherein the element III nitride is an alloy comprising GaN and GaInN, and the substrate is on a GaPO₄ substrate.

5. The process as claimed in claim 1, wherein the growing of the element III nitride on the substrate is carried out via epitaxy.

6. The process as claimed in claim 1, wherein the growing of the element III nitride on the substrate is carried out via sputtering.

7. A structure for application in electronics, optics or optoelectronics comprising element III nitride deposited on a substrate made of material for retaining the same crystalline structure from the growing temperature of the element III nitride to ambient temperature, the substrate being an alloy of M-V—O₄ type, where M designates a transition metal or an element of group III, where V designates N, P, As or Sb, or an alloy of (Si-IV)O₂ type, and where IV designates an element of group IV other than silicon.

8. An electronic, optic or optoelectronic component comprising element III nitride deposited on a substrate made of material for retaining the same crystalline structure from the growing temperature of the element III nitride to ambient temperature the substrate being an alloy of M-V—O₄ type where M designates a transition metal or an element of group III, where V designates N, P, As or Sb, or an alloy of (Si-IV)O₂ type, and where IV designates an element of group IV other than silicon.

9. The component as claimed in claim 8, from electroluminescent diodes, laser diodes and transistors.

10. The process as claimed in claim 1, further comprising making at least one of an electronic, optic and optoelectronic component to include the element Ill nitride deposited on the substrate.
